(19) United States
(12) Patent Application Publication
(10) Pub. No.: US 2025/0085179 A1
(43) Pub. Date: Mar. 13, 2025

(54) PRESSURE SENSOR WITH INTEGRATED FLUID CAVITY

(71) Applicant: Apple Inc., Cupertino, CA (US)

(72) Inventors: Michael J. GLICKMAN, Mountain View, CA (US); Kuolung LEI, San Jose, CA (US); Gregory B. ARNDT, San Jose, CA (US)

(21) Appl. No.: 18/626,075

(22) Filed: Apr. 3, 2024

Related U.S. Application Data
(60) Provisional application No. 63/582,452, filed on Sep. 13, 2023.

(51) Int. Cl. G01L 9/00; B81B 3/00; G01L 9/06; G04G 21/02

(52) U.S. Cl. CPC G01L 9/0054; B81B 3/0021; G01L 9/065; G04G 21/02; B81B 2201/0264; B81B 2203/0127

(57) ABSTRACT

Aspects of the subject technology relate to electronic devices with pressure sensors having an integrated fluid cavity. The electronic device includes a housing having an opening. The electronic device also includes a pressure sensor disposed within the housing and adjacent to the opening. The pressure sensor includes a substrate and a sensing membrane disposed on the substrate that is configured to obtain pressure data. The pressure sensor also includes a membrane support disposed on the substrate and an outer membrane disposed on the membrane support. The pressure sensor also includes reference cavity formed between the sensing membrane and the substrate. The pressure sensor also includes a fluid cavity disposed between the sensing membrane and the outer membrane. In some aspects, the outer membrane forms a hermetic seal around the fluid cavity. In other aspects, the outer membrane has a stiffness that is lesser than the sensing membrane.

### CROSS-REFERENCE TO RELATED APPLICATION(S)

This application claims the benefit of U.S. Provisional Application Ser. No. 63/582,452, entitled “PRESSURE SENSOR WITH INTEGRATED FLUID CAVITY,” and filed on Sep. 13, 2023, the disclosure of which is expressly incorporated by reference herein in its entirety.

### TECHNICAL FIELD

The present description relates generally to portable electronic devices, and more particularly, but not exclusively, to portable electronic devices with pressure sensors.

### BACKGROUND

Electronic pressure sensors are often used to obtain barometric pressure measurements for elevation and/or weather measurements. However, challenges can arise when attempting to implement an electronic pressure sensor in a portable electronic device.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates a schematic diagram of an electronic device having a pressure sensor in accordance with various aspects of the subject technology.

FIG. 2 illustrates a perspective view of an example electronic device implemented as a wearable device in accordance with various aspects of the subject technology.

FIG. 3 illustrates a cross-sectional side view of a pressure sensor with an integrated fluid cavity disposed in a pressure sensor port in a housing of an electronic device in accordance with various aspects of the subject technology.

FIG. 4 illustrates a cross-sectional side view of a pressure sensor with an integrated fluid cavity and surface corrugated membrane disposed in a pressure sensor port in a housing of an electronic device in accordance with various aspects of the subject technology.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced without these specific details. In some instances, well-known structures and components are shown in block diagram form in order to avoid obscuring the concepts of the subject technology.

Portable electronic devices such as a mobile phones, portable music players, smart watches, and tablet computers are provided that include a pressure sensor for sensing environmental pressure. The pressure sensor is sometimes used for barometric pressure measurements, which can be used to identify changes in elevation. The changes in elevation are sometimes used to identify a location or exercise performed by a user of the device (e.g., by an activity monitor application running on processing circuitry of the device when the device is worn or carried by the user while the user walks or runs up a flight of stairs or up a hill).

Pressure sensors are disposed within a housing of the portable electronic device and can sense the environmental pressure outside the housing due to airflow from outside the housing into the housing at various openings or ports. Similarly, a microphone may be disposed within the housing of the portable electronic device and can output audible sound through an opening or port in the housing. However, directly exposing an integrated pressure sensor to some environments can lead to permanent damage or parametric shifts due to contaminants (e.g., dust, salt, water, etc.) in the environment.

Portable electronic devices most commonly use capacitive or piezo-resistive micro-electromechanical system (MEMS) pressure sensors. MEMS pressure sensors used in consumer electronic devices are operational within a defined pressure range (e.g., 30 kPa-110 kPa). MEMS pressure sensors typically rely on a diaphragm that deflects to detect pressure change. The performance of the sensor is dependent on the sensor's linearity. The linearity of the sensor decreases as the diaphragm deflection increases. Typical MEMS pressure sensors have a single diaphragm and a single sealed cavity, which is typically at a vacuum pressure.

In the field of pressure sensing technology, oil-filled pressure sensors exhibit resilience against environmental challenges. However, their advantages come coupled with certain limitations. These oil-filled pressure sensors possess substantial physical dimensions and are further hindered by the rigidity of their outer membrane. This inflexibility contributes to a pronounced high uncompensated temperature coefficient of offset (TCO) within the pressure sensor's performance. Despite attempts at calibration, completely eliminating this TCO remains elusive.

Similarly, gel-based pressure sensors warrant attention due to their vulnerability to expansion when exposed to aggressive chemicals. This expansion limitation impacts their utility. Furthermore, unprotected pressure sensors face accuracy and TCO alterations, triggered by particle bonding to the pressure sensor's membrane. Maintaining consistent performance in the face of particle bonding poses a significant challenge.

Addressing these shortcomings, a common approach involves waterproof encapsulation or utilizing waterproof membranes and/or mesh. However, such mitigations remain susceptible to mechanical failures, including exposure to high-velocity water or damage from probing during device usage.

In a departure from traditional oil-filled pressure sensor designs, the subject technology involves the formation of an outer membrane from resilient silicon material, deposited onto a MEMS pressure sensor during subsequent micro-fabrication stages. This transformation from a conventional macroscopic cavity to a MEMS fluid cavity yields a substantial reduction in dimensions, significantly diminishing the size. Moreover, this technique yields a marked decrease in inherent TCO, achieved through the utilization of a thin outer MEMS membrane known for its temperature stability. This outer membrane, potentially much larger in width than the sensing membrane and with a relatively thin profile. In one or more implementations, the outer membrane can be fabricated to be substantially thinner than bulk fabricated membranes utilized in oil-based pressure sensors. The lower stiffness of the outer membrane means that contaminants like particles or films have less influence on the sensitivity of the inner membrane or its TCO-contrasting with direct contamination effects on the MEMS sensing membrane.

The subject technology includes a fluid medium between the outer and sensing membranes, enabling pressure transmission. In contrast to oil-based pressure sensors with sizable oil-filled cavities, the subject technology integrates the oil-filled or fluid cavity directly into a MEMS structure. As such, TCO mitigation can be further achieved by utilizing a membrane support material with a TCO that is substantially similar or identical to that of the fluid, enhancing overall performance. The intrinsic TCO of the MEMS membrane is substantially reduced due to its thin composition, closely approximating the native TCO observed without a built cavity or outer membrane. This reduction in TCO sets the subject technology apart from traditional oil-filled pressure sensors. Facilitating precise fluid cavity filling can be achieved through a vacuum-based process using capillary forces, complemented by laser sealing techniques to hermetically seal the outer cavity.

The primary objective of incorporating the fluid-filled cavity is twofold: enabling pressure detection while mitigating potential influences from particles or contaminants on the membrane's surface. Achieved through a thin outer membrane, its intrinsic pliability and reduced susceptibility to pressure fluctuations from external factors are evident. Due to its slender nature, in one or more implementations, certain vulnerabilities persist; a puncture, for instance, can impair the outer membrane. Consequently, in one or more implementations, an additional layer of protection, such as an encompassing mesh or cap, can be added.

This integration yields numerous advantages. Firstly, it results in size reduction and potentially substantial cost savings. Secondly, it facilitates the fabrication of exceedingly thin MEMS membranes. Overall, this integration represents an advancement in pressure sensing technology, enhancing robustness and efficiency while addressing prior limitations.

Embodiments of the subject technology provide for electronic devices with pressure sensors having an integrated fluid cavity. The electronic device includes a housing having an opening. The electronic device also includes a pressure sensor disposed within the housing and adjacent to the opening. The pressure sensor includes a substrate and a sensing membrane disposed on the substrate that is configured to obtain pressure data. The pressure sensor also includes a membrane support disposed on the substrate and an outer membrane disposed on the membrane support. The pressure sensor also includes a reference cavity formed between the sensing membrane and the substrate. The pressure sensor also includes a fluid cavity disposed between the sensing membrane and the outer membrane. In some aspects, the outer membrane forms a hermetic seal around the fluid cavity. In other aspects, the outer membrane has a thickness that is smaller than the sensing membrane. In still other aspects, the outer membrane has a width that is greater than the sensing membrane.

In accordance with various aspects of the subject disclosure, a smart watch is provided that includes a housing having an opening. The smart watch also includes a pressure sensor disposed within the housing and adjacent to the opening. The pressure sensor includes a substrate; a sensing membrane disposed on the substrate and configured to obtain pressure data; a membrane support disposed on the substrate; an outer membrane disposed on the membrane support; reference cavity formed between the sensing membrane and the substrate; and a fluid cavity disposed between the sensing membrane and the outer membrane, in which the outer membrane forms a hermetic seal around the fluid cavity, and in which the outer membrane has a thickness that is similar to the sensing membrane.

In accordance with other aspects of the subject disclosure, an electronic device is provided that includes a housing having an opening. The electronic device also includes a pressure sensor disposed within the housing and adjacent to the opening. The pressure sensor includes a sensing membrane configured to obtain pressure data; a membrane support; an outer membrane; and a fluid cavity disposed between the sensing membrane and the outer membrane, in which the outer membrane is disposed on the membrane support and encapsulates the fluid cavity and the sensing membrane.

In accordance with other aspects of the subject disclosure, an apparatus is provided that includes a substrate; a sensing membrane disposed on the substrate and configured to obtain pressure data; a membrane support disposed on the substrate; an outer membrane disposed on the membrane support; reference cavity formed between the sensing membrane and the substrate; and a fluid cavity disposed between the sensing membrane and the outer membrane, in which the outer membrane encapsulates the fluid cavity and the sensing membrane.

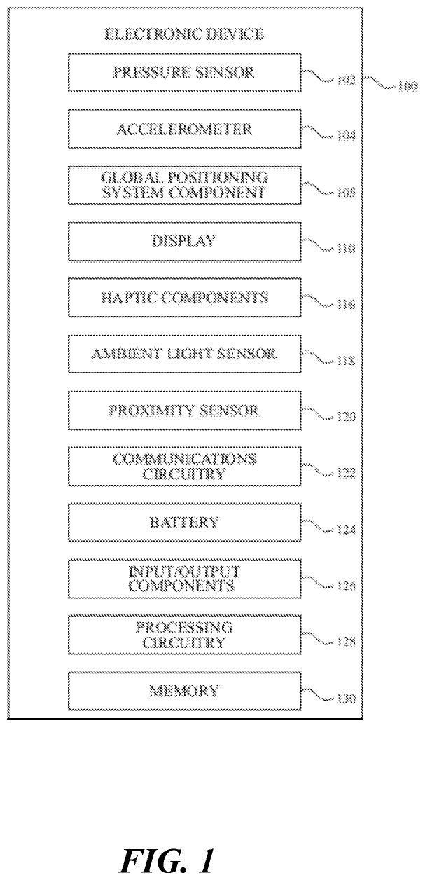

A schematic block diagram of an illustrative electronic device with a pressure sensor is shown in FIG. 1. In the example of FIG. 1, device 100 includes pressure sensor 102 and accelerometer 104. Pressure sensor 102 includes a pressure sensing element (e.g., a micro-electromechanical system element, a piezo element, a membrane coupled to a capacitive or resistive transducer circuit, etc.) and may include processing circuitry 128 for pressure sensor 102. Accelerometer 104 includes electronic components that generate an acceleration signal responsive to physical accelerations of accelerometer 104 (e.g., due to acceleration of device 100).

Device 100 also includes processing circuitry 128 and memory 130. Memory 130 may include one or more different types of storage such as nonvolatile memory (e.g., flash memory or other electrically-programmable-read-only memory), volatile memory (e.g., static or dynamic random-access-memory), magnetic or optical storage, permanent or removable storage and/or other non-transitory storage media configure to store static data, dynamic data, and/or computer readable instructions for processing circuitry 128. Processing circuitry 128 may be used in controlling the operation of device 100. Processing circuitry 128 may sometimes be referred to as system circuitry or a system-on-chip (SOC) for device 100.

Processing circuitry 128 may include a processor such as a microprocessor and other suitable integrated circuits, multi-core processors, one or more application specific integrated circuits (ASICs) or field programmable gate arrays (FPGAs) that execute sequences of instructions or code, as examples. In one suitable arrangement, processing circuitry 128 may be used to run software for device 100, such as activity monitoring applications, pressure sensing applications, acceleration sensing application, occlusion detection applications using pressure data and accelerometer data, internet browsing applications, email applications, media playback applications, operating system functions, software for capturing and processing images, software implementing functions associated with gathering and processing sensor data, software that controls audio, visual, and/or haptic functions.

In the example of FIG. 1, device 100 also includes display 110, communications circuitry 122, battery 124, and input/output components 126. Input/output components 126 may include a touch-sensitive layer of display 110, a keyboard, a touch-pad, and/or one or more real or virtual buttons. Input/output components 126 may also include audio components such as one or more speakers and/or one or more microphones. In some scenarios a speaker membrane or a microphone membrane can be operated to move air to affect and/or clear occlusions of one or more ports in a housing of device 100.

Communications circuitry 122 may be implemented using WiFi, near field communications (NFC), Bluetooth®, radio, microwave, and/or other wireless and/or wired communications circuitry. Communications circuitry 122 may be operated by processing circuitry 128 based on instructions stored in memory 130 to perform cellular telephone, network data, or other communications operations for device 100. Communications circuitry 122 may include WiFi and/or NFC communications circuitry operable to communicate with an external device such a mobile telephone or other remote computing device. In some scenarios, data communications with an external device such as communications by circuitry 122 of a smart watch with a host mobile phone may allow the use of data from the external device, in combination with pressure sensor data and/or acceleration data from the watch to identify and/or characterize a pressure sensor occlusion.

As shown in FIG. 1, device 100 may include other components such as a global positioning system (GPS) component 105, haptic components 116 (e.g., one or more vibratory or other actuable devices that can produce tactile and/or audible responses for a user and/or other desired accelerations of device 100), and/or other sensors such as ambient light sensor 118 and/or proximity sensor 120.

In some scenarios, GPS data (e.g., elevation data) from GPS component 105, ambient light data from ambient light sensor 118, and/or proximity sensor data from proximity sensor 120 may be used, in combination with pressure data from pressure sensor 102 and acceleration data from accelerometer 104 to identify an occlusion of pressure sensor 102 and/or identify an occluding aggressor. For example, ambient light data and/or proximity sensor data may be used, after a pressure sensor occlusion is detected using both pressure data and accelerometer data, to determine whether the pressure sensor port is covered by an opaque object such as a long-sleeved clothing item or a user's own skin.

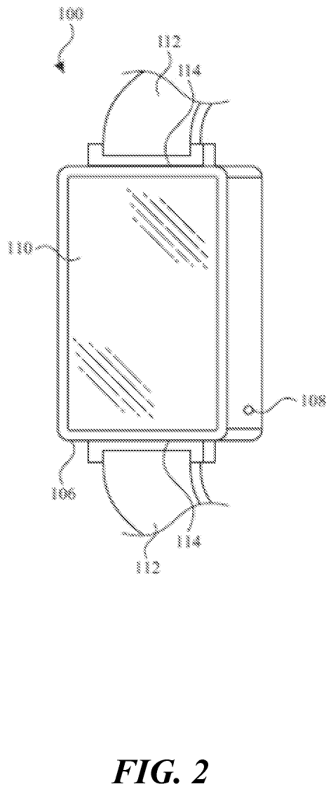

FIG. 2 is a perspective view of electronic device 100 in a configuration in which electronic device 100 has been implemented in the form of a wearable device such as smart watch. Although FIG. 2 depicts a smart watch, embodiments are not so limited. For example, electronic device 100 may be a mobile phone, laptop, tablet computer, head mounted device, etc. As shown in FIG. 2, display 110 may be disposed on a front surface of housing 106. Housing 106 may include one or more openings such as opening 108. In the example of FIG. 2 opening 108 is formed in a sidewall of housing 106 and provides a fluid coupling for airflow between an environment external to housing 106 into a portion of housing 106. Pressure sensor 102 (FIG. 1) may be disposed internal to housing 106 adjacent to opening 108 to receive airflow from the external environment through opening 108.

Any or all of components 104, 104, 105, 116, 118, 120, 124, 126, 128, and 130 of FIG. 1 may be disposed on or within housing 106. One or more additional openings in housing 106 may be provided for a speaker, a microphone, an ambient light sensor, and/or a proximity sensor. Strap 112 may be coupled to housing 106 at interfaces 114 and arranged to secure device 100 to a part of a user's body such as around the user's wrist.

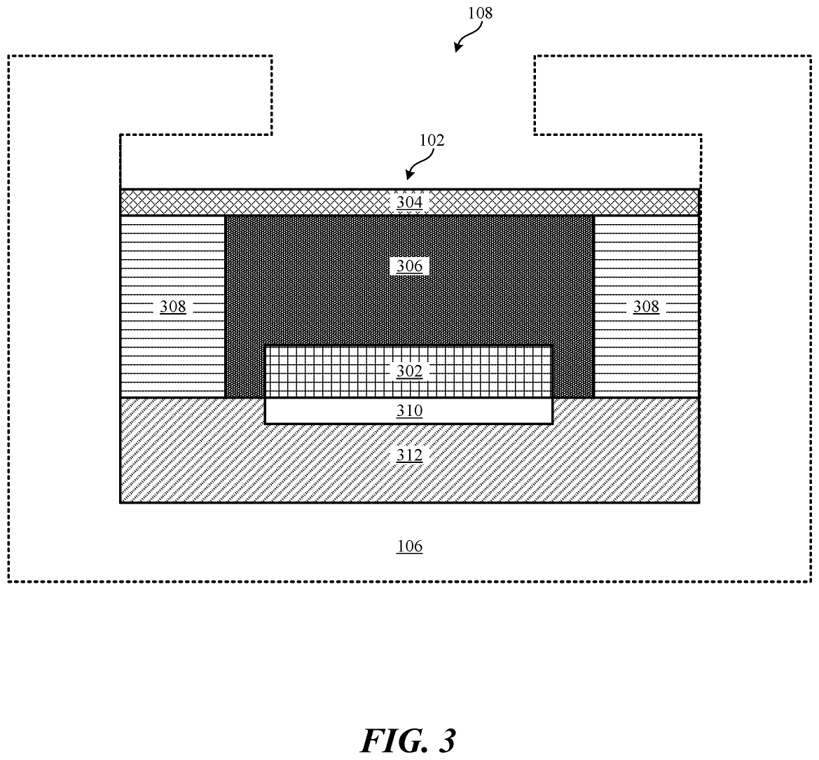

FIG. 3 illustrates a cross-sectional side view of pressure sensor 102 with an integrated fluid cavity disposed in a pressure sensor port in housing 106 of an electronic device 100 in accordance with various aspects of the subject technology. In the example of FIG. 3, pressure sensor 102 may be provided with access to the airflow from the external environment through 108. Specifically, FIG. 3 shows a cross-sectional side view of a portion of device 100 at the location of opening 108. As shown in FIG. 3, pressure sensor 102 is disposed within housing 106 adjacent opening 108 such that pressure sensor 102 receives an inflow through opening 108. A pressure sensor port for pressure sensor 102 is formed by opening 108, within housing 106, within which pressure sensor 102 is disposed. Pressure sensor 102 includes sensing membrane 302, outer membrane 304, fluid cavity 306, membrane support 308, reference cavity 310 and substrate 312.

Housing 106 can be made, for example, from a metal such as aluminum or stainless steel, but is not limited to these metals, and can be made of any qualified metal or other material. Opening 108 in housing 106 allows exposure to the surrounding environment. In some aspects, the surrounding environment can be a liquid such as water, in which case pressure sensor 102 is a liquid (water) pressure sensor and opening 108 exposes device 100 to the liquid that forms an inflow. In other aspects, the surrounding environment can be an atmosphere, for which case pressure sensor 102 is a barometric pressure sensor and opening 108 exposes device 100 to the inflow, which in this case can be a gas (e.g., air). Pressure sensor 102 is protected from the potentially harsh environments it needs to operate in (e.g., water) and damage due to probing, or the like. In addition, this protection should reduce any error in the pressure reading of pressure sensor 102, for example, due to noise, offset, or latency in pressure measurement.

Sensing membrane 302 is disposed within fluid cavity 306 and positioned on a top surface of substrate 312. In one or more implementations, reference cavity 310 is formed beneath the sensing membrane 310. Substrate 312 can be, for example, a semiconductor substrate. In one or more implementations, the semiconductor is silicon such as p-doped silicon substrate and reference cavity 310 is created in the p-doped silicon substrate using a silicon-etch procedure (e.g., a wet or dry etch).

The width of reference cavity 310 may be comparable to the width of sensing membrane 302 such that reference cavity 310 may include a width in a range that corresponds to that of sensing membrane 302 but may vary depending on implementation. The height of reference cavity 310 may vary depending on implementation. Reference cavity 310 may be formed using an etch process in substrate 312. In one or more implementations, reference cavity 310 may include a specified pressure level that tends to dwell within the realm of near-vacuum conditions, delineating an alignment with the lower end of the pressure spectrum (e.g., <0.1 atm).

Sensing membrane 302 functions as the pressure-sensitive element. In one or more implementations, sensing membrane 302 operates as a piezo resistivity sensing mechanism. In one or more other implementations, sensing membrane 302 operates as a capacitance sensing mechanism.

As illustrated in FIG. 3, outer membrane 304 is disposed across fluid cavity 304 and on top surfaces of membrane support 308. In one or more implementations, the sealing of outer membrane 304 is achieved through the utilization of laser sealing, achieving a hermetic seal that encapsulates the enclosed environment within (e.g., fluid cavity 306).

Previous approaches involved employing metal-based membranes as part of a larger assembly. In contrast, outer membrane 304 is integrated as part of the pressure sensor fabrication process and can employ a semiconductor material, such as silicon. The fabrication of outer membrane 304 may entail alternative options, extending beyond silicon to encompass materials such as nitride and oxide. Varieties of nitride, specifically stress-free nitride contingent upon design considerations, emerge as a viable choice. Such nitride varieties may possess heightened tensile strength, aiming to address specific design challenges. Diverse deposition processes can be utilized to achieve this objective. The fabrication of outer membrane 304 may entail a broadened material spectrum including nitride varieties that encompass high-stress nitride, low-stress nitride, and other comparable variations.

The fundamental objective of both gel-based and fluid-based configurations is to convey substantially similar pressure to sensing membrane 302, akin to the absence of the encapsulating medium. The structure shown in FIG. 3 can shield sensing membrane 302 from particle-induced interference, which facilitates accurate measurement. When particles reside upon sensing membrane 302 in the absence of gel or fluid encapsulation, they impose constraints that distort the sensing mechanism, inducing erroneous outcomes. Gel serves to mitigate the impact of particles in one or more implementations, whereas fluid integration operates in a comparable manner in one or more other implementations, whereby the particles' influence is averaged across outer membrane 304.

In one or more implementations, membrane materials possessing specific properties are compatible with moisture protection. For instance, components such as sensing membrane 302 and membrane support 308 can demonstrate a moisture barrier property. The widely used measure for this characteristic represents the rate of water vapor transmission, and it is desirable to minimize this value, ideally aiming for zero.

Additionally, the utilization of materials beyond silicon, such as oxide, is not precluded. However, moisture impact on the material used for outer membrane 304 may be considered. As moisture may potentially compromise the fluid enclosed within fluid cavity 306, in one or more implementations, materials susceptible to moisture penetration, like oxide, warrant cautious assessment. In contrast to a gel-based pressure sensor, outer membrane 304 exhibits enhanced impermeability.

In one or more implementations, the materials used for membrane fabrication of outer membrane 304 can achieve a desired membrane stiffness that is notably lower than that of sensing membrane 302, with a targeted reduction factor of approximately 10× to even 100×. In other words, outer membrane 304 may be about 10× to about 1000× less stiff than sensing membrane 302. This characteristic contributes to a form of mechanical transparency, facilitating the unimpeded transmission of phenomena. While sensing membrane 302 is characterized by thinness and smaller dimensions, proportional to the cubic relationship with size of fluid cavity 306, outer membrane 304 is by implementation substantially less stiff than traditional outer membranes of fluid-filled sensor and MEMS sensing membranes.

As discussed above, there may be a relationship measured between outer membrane 304 and sensing membrane 302 concerning stiffness, where the aim is to maintain a stiffness level that is notably lower by a factor of at least 10× to about 1000×. This relationship translates to an inherently thin outer membrane 304, falling within the sub-micron scale. This relationship arises from the intention to utilize the same membrane configuration to isolate the environment from the underlying sensing membrane 302. Thereby, this stiffness relationship serves as a criterion that facilitates that the spring constant of outer membrane 304 is substantially lower than that of sensing membrane 302, thus evading the undesired elevation of native thermal coefficient performance.

The metal membranes exhibit a stiffness and thickness greater than silicon or nitride membranes. For instance, the metal membranes have a thickness of approximately 12.5 microns, translating to substantially larger stiffness magnitudes above the range of typical flexible materials. In contrast, the silicon or nitride membranes are projected to possess a nominal thickness of around one micron or less. Furthermore, the silicon membrane configuration can be fabricated at wafer scale in a same fabrication process as the MEMS pressure sensor, fostering a compact form factor and cost efficiency through the integration of patch and concept on the wafer plane. This culminates in reduced form factor dimensions and streamlined cost considerations.

In one or more implementations, outer membrane 304 may include a thickness of about one micron. In one or more other implementations, outer membrane 304 may include a thickness of about 0.3 microns. In one or more implementations, the thickness of the outer membrane 304 may be in the range of 0.2 microns to 25 microns. In one or more implementations, the width of outer membrane 304 may be in the range of 200 microns to 2 millimeters.

In one or more implementations, the thickness of sensing membrane 302 may be in the range of 0.1 microns to 10 microns. Nonetheless, the overarching objective resides in facilitating that outer membrane 304 remains less stiff than sensing membrane 302, although this relationship is also influenced by dimensions. In specific instances, outer membrane 304 may exhibit greater thickness than sensing membrane 302, provided its width compensates for the stiffness disparity. The interplay of width and stiffness assumes paramount importance.

In one or more implementations, the width of sensing membrane 302 may be in the range of 20 microns to 500 millimeters. In one or more other implementations, the width of sensing membrane 302 may be in the range of 500 microns to 1 millimeter. In one or more other implementations, sensing membrane 302 may have a width of about 100 microns.

In relation to a gel-based pressure sensor, there exists the possibility of a higher inherent TCO, assuming parity between the thermal expansion of membrane support 308 and that of the fluid contained within fluid cavity 306. In some aspects, the native TCO reflects the pressure-area error, measured in pascals, corresponding to a temperature change of one Celsius degree. In one or more implementations, the TCO is a parameter minimized by calibration, where highly nonlinear TCOs may be, in one or more implementations, difficult to compensate for with calibration. Stability over time facilitates successful calibration and large native TCOs may require greater stability, resulting in a higher TCO even after compensation.

In one or more implementations, fluid cavity 306 encompasses various fluids, including oils, which may be associated with specific oils, materials, or fluid classifications. In one or more implementations, the fluids encompassed within fluid cavity 306 are stable oils. For example, the fluid may be implemented as flourosilicone oil. In one or more other implementations, the fluid may be implemented as silicone oil. The fluids contained within fluid cavity 306 may include specific properties characterizing a “stable oil.” In some aspects, fluid cavity 306 may include a fluid based on a property such as constancy in terms of the coefficient of thermal expansion (CTE). In some aspects, fluid cavity 306 may include a fluid based on another property such as incompressibility, which is prevalent in numerous fluids. For example, the range for incompressibility may be close to zero (e.g., <10⁻⁶) change in volume under pressure. In other aspects, the fluid cavity 306 may include a fluid having a certain level of water absorption, despite the intention to curtail water permeation through outer membrane 304, in one or more implementations. For example, a fluid with minimal water absorption may have an absorption rate of less than 0.1% by weight. Optimal fluid candidates ideally exhibit minimal water absorbency. Moreover, the boiling point of a fluid may be another criterion. For example, fluid cavity 306 may include a fluid having an elevated boiling point, preferably higher than required for solder reflow (e.g., such as a range starting at around 250 degrees Celsius).

The fluids contained within fluid cavity 306 may include additional properties conducive to the administration of oil within fluid cavity 306. In some aspects, fluid cavity 306 may include a fluid based on its viscosity. Furthermore, embodiments of the subject technology attempt to prioritize reduced coefficients of thermal expansion.

In one or more implementations, fluid cavity 306 is sealed to facilitate complete absence of air bubbles. A comprehensive fill of oil facilitates a direct translation of pressure. In one or more implementations, fluid cavity 306 may include a certain level of sensitivity such that, in one or more implementations, may cause it to be susceptible to air bubble presence. In this regard, fluid cavity 306 may be configured with a permissible air bubble tolerance to facilitate accurate measurement of pressure transmission.

Fluid cavity 306 may have a height of about 15 microns, denoting the space between the sensing membrane 302 and the outer membrane 304. The height of fluid cavity 306 may be in the range of 1 micron to 15 microns. In one aspect, the height of fluid cavity 306 may be measured from the uppermost surface of sensing membrane 302 to the bottom surface of outer membrane 304. In another aspect, the height of fluid cavity 306 may be measured from the uppermost surface of substrate 312 to the bottom surface of outer membrane 304. In one or more implementations, the configuration of fluid cavity 306 may be governed by the height and width of fluid cavity 306. In one or more implementations, smaller fluid cavity heights may reduce g-sensitivity. In this regard, g-sensitivity may refer to the sensitivity of a pressure sensor to changes in acceleration or gravitational forces (g-forces). For example, the fluid cavity height may be about 0.1 microns. In one or more other implementations, larger fluid cavity heights may provide greater protection of the sensing membrane 302.

In some aspects, electromagnetic radiation exposure (e.g., a spectrum of electromagnetic waves encompassing various wavelengths, including ultraviolet (UV), visible light, and infrared (IR)) may influence the operation of the pressure sensor 102 based on a sensing type. The electromagnetic radiation exposure tends to influence a piezo resistivity sensing mechanism rather than a capacitance sensing mechanism. Depending on the sensing type of sensing membrane 302, the electromagnetic radiation exposure may have a potential impact on the embedded strain sensors of sensing membrane 302. The relevance of electromagnetic radiation opacity hinges upon the specific characteristics of sensing membrane 302 underlying fluid cavity 306. Opacity of outer membrane 304 can be influenced by its interaction with the electromagnetic radiation, predominantly dictated by the nature of sensing membrane 302. To achieve a level of opacity on outer membrane 304, a metal or a thin metal coating may be disposed on outer membrane 304 in one or more implementations, or as part of the system integration in one or more other implementations. With the introduction of one or more layers on outer membrane 304 for achieving opacity, in one or more implementations, potential thermal implications, including drift and thermal actuation, should be balanced, which can inadvertently affect the CTE. In one or more implementations, a layer of silicon can be disposed atop outer membrane 304. In one or more other implementations, an exceedingly thin layer of metal, approximately 50 nanometers, can be disposed atop outer membrane 304.

In further contrast to a gel-based pressure sensor, pressure sensor 102 of FIG. 3 exhibits a compact nature, facilitating enhanced form factor designs. In terms of applicability, pressure sensor 102 can be found in more rugged form factors, such as wearable devices like watches or phones. The compactness of pressure sensor 102 with the integrated fluid cavity 306 lends itself well to such designs.

In one or more implementations, the native TCO encompasses the entire structure and incorporates factors such as substrate attachment, protective mechanisms, and circuit-related changes, amalgamating these into a singular element for assessment. In one or more implementations, the TCO of membrane support 308 should align with that of the fluid contained within fluid cavity 306, facilitating compatibility. Fluid cavity 306 and membrane support 308 can expand at congruent rates to prevent forces impacting sensing membrane 302. This alignment extends to fluid properties, with materials that typically exhibit lower TCO values compared to fluids with higher ppm levels. In the quest for harmonization, the subject technology attempts to balance the fluid's CTE with the spring constant of sensing membrane 302, thereby negating undue pressure on pressure sensor 102.

In one or more implementations, membrane support 308 may include polymer-based materials that potentially reduce stiffness. The challenge with polymer-based structures, in one or more implementations, lies in the variation in their CTE values across different lots, introducing variability. Nonetheless, fabrication of membrane support 308 may integrate a polymer process into the MEMS framework, thereby achieving comparable and stable CTE characteristics to those of the fluid. In addition, if the polymer membrane stiffness is sufficiently low (e.g., below a predefined stiffness threshold), stiffness variation by lot and over time, may be tolerable.

In one or more implementations, the use of fluid-based interior fills may be facilitated with one or more sealing processes. In one or more other implementations, the use of a soft gel as an alternative interior fill material can offer advantages over fluid-based interior fills such as simplified sealing processes while addressing certain features, such as increased g-sensitivity (from inferior thickness control), processing challenges, and tackiness associated with an external gel layer. A gel-based interior fill may involve the use of a substantially soft gel as an alternative to a fluid. An advantage of employing the soft gel, among others, is its potential to eliminate the need for sealing, a common requirement in fluid-based interior fills. This soft gel, when utilized as an interior fill material, may be disposed into the fluid cavity 306 through a process similar to the oil filling method. However, instead of sealing the gel-filled fluid cavity 306, it would undergo a curing process. This could lead to simplified manufacturing processes, reduced maintenance, and enhanced reliability in MEMS pressure sensors. Moreover, the absence of seals may contribute to improved longevity and reduced risk of leaks or contamination. In one or more implementations, the use of a soft gel may necessitate layers of the material that are thicker than those used with fluid-based interior fills to achieve an equivalent level of particulate protection compared to fluid-based interior fills. This increased thickness may introduce a higher level of g-sensitivity, which can be mitigated in one or more implementations of the pressure sensor 102.

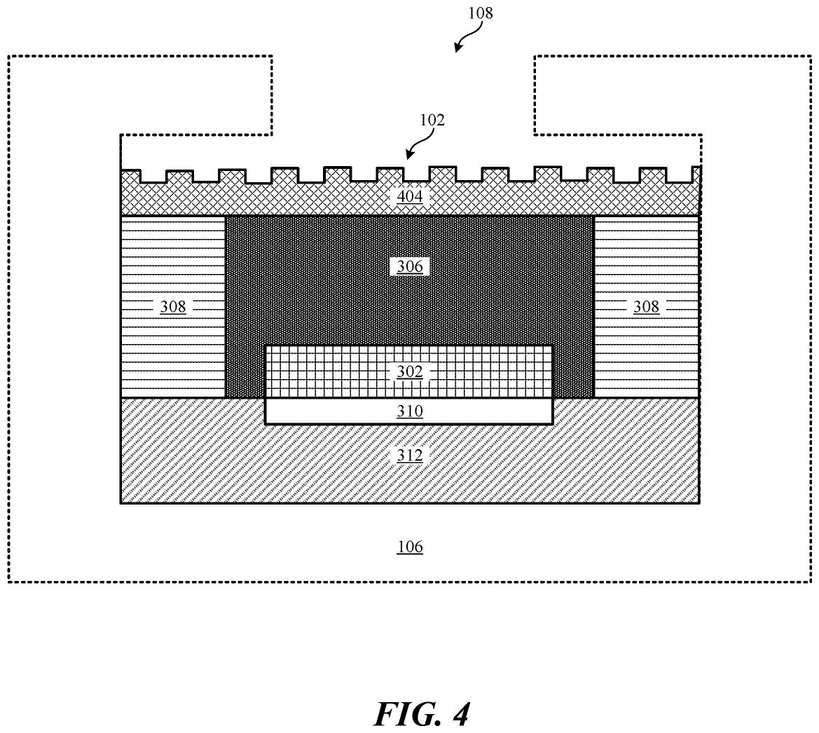

FIG. 4 illustrates a cross-sectional side view of a pressure sensor with an integrated fluid cavity and surface corrugated membrane disposed in a pressure sensor port in a housing of an electronic device in accordance with various aspects of the subject technology. In the example of FIG. 4, pressure sensor 102 may be provided with access to the airflow from the external environment through 108. Specifically, FIG. 4 shows a cross-sectional side view of a portion of device 100 at the location of opening 108. As shown in FIG. 4, pressure sensor 102 is disposed within housing 106 adjacent opening 108 such that pressure sensor 102 receives an inflow through opening 108. A pressure sensor port for pressure sensor 102 is formed by opening 108, within housing 106, within which pressure sensor 102 is disposed. Pressure sensor 102 includes sensing membrane 302, outer membrane 404, fluid cavity 306, membrane support 308, reference cavity 310 and substrate 312.

The pressure sensor depicted in FIG. 4 is substantially to the pressure sensor depicted in FIG. 3; and therefore, only the differences will be described with reference to FIG. 4 for purposes of brevity in explanation. As illustrated in FIG. 4, outer membrane 404 is disposed across fluid cavity 404 and on top surfaces of membrane support 308. In one or more implementations, outer membrane 404 includes a corrugated surface. In one or more implementations, the corrugated surface (e.g., top, bottom or both) may include a pattern of ridges and troughs. In one or more implementations, outer membrane 404 may include a second sacrificial layer that is patterned during fabrication to produce the pattern of ridges or troughs, reducing its stiffness. In one or more implementations, a top surface of outer membrane 404 (e.g., the surface of outer membrane 404 facing opening 108) is corrugated. In one or more other implementations, a bottom surface of outer membrane 404 (e.g., the surface facing fluid cavity 306) is corrugated. In one or more other implementations, both the top surface and the bottom surface of outer membrane 404 are corrugated.

Various functions described above can be implemented in digital electronic circuitry, in computer software, firmware or hardware. The techniques can be implemented using one or more computer program products. Programmable processors and computers can be included in or packaged as mobile devices. The processes and logic flows can be performed by one or more programmable processors and by one or more programmable logic circuitry. General and special purpose computing devices and storage devices can be interconnected through communication networks.

Some implementations include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD-RW, DVD+RW, etc.), flash memory (e.g., SD cards, mini-SD cards, micro-SD cards, etc.), magnetic and/or solid state hard drives, ultra density optical discs, any other optical or magnetic media. The computer-readable media can store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

While the above discussion primarily refers to microprocessor or multi-core processors that execute software, some implementations are performed by one or more integrated circuits, such as application specific integrated circuits (ASICs) or field programmable gate arrays (FPGAs). In some implementations, such integrated circuits execute instructions that are stored on the circuit itself.

As used in this specification and any claims of this application, the terms “computer”, “processor”, and “memory” all refer to electronic or other technological devices. These terms exclude people or groups of people. For the purposes of the specification, the terms “display” or “displaying” means displaying on an electronic device. As used in this specification and any claims of this application, the terms “computer readable medium” and “computer readable media” are entirely restricted to tangible, physical objects that store information in a form that is readable by a computer. These terms exclude any wireless signals, wired download signals, and any other ephemeral signals.

To provide for interaction with a user, implementations of the subject matter described in this specification can be implemented on a computer having a display device as described herein for displaying information to the user and a keyboard and a pointing device, such as a mouse or a trackball, by which the user can provide input to the computer. Other kinds of devices can be used to provide for interaction with a user as well; for example, feedback provided to the user can be any form of sensory feedback, such as visual feedback, auditory feedback, or tactile feedback; and input from the user can be received in any form, including acoustic, speech, or tactile input.

Many of the above-described features and applications are implemented as software processes that are specified as a set of instructions recorded on a computer readable storage medium (also referred to as computer readable medium). When these instructions are executed by one or more processing unit(s) (e.g., one or more processors, cores of processors, or other processing units), they cause the processing unit(s) to perform the actions indicated in the instructions. Examples of computer readable media include, but are not limited to, CD-ROMs, flash drives, RAM chips, hard drives, EPROMs, etc. The computer readable media does not include carrier waves and electronic signals passing wirelessly or over wired connections.

In this specification, the term “software” is meant to include firmware residing in read-only memory or applications stored in magnetic storage, which can be read into memory for processing by a processor. Also, in some implementations, multiple software aspects of the subject disclosure can be implemented as sub-parts of a larger program while remaining distinct software aspects of the subject disclosure. In some implementations, multiple software aspects can also be implemented as separate programs. Finally, any combination of separate programs that together implement a software aspect described here is within the scope of the subject disclosure. In some implementations, the software programs, when installed to operate on one or more electronic systems, define one or more specific machine implementations that execute and perform the operations of the software programs.

A computer program (also known as a program, software, software application, script, or code) can be written in any form of programming language, including compiled or interpreted languages, declarative or procedural languages, and it can be deployed in any form, including as a standalone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

It is understood that any specific order or hierarchy of blocks in the processes disclosed is an illustration of example approaches. Based upon design preferences, it is understood that the specific order or hierarchy of blocks in the processes may be rearranged, or that all illustrated blocks be performed. Some of the blocks may be performed simultaneously. For example, in certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

The predicate words “configured to”, “operable to”, and “programmed to” do not imply any particular tangible or intangible modification of a subject, but, rather, are intended to be used interchangeably. For example, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code

A phrase such as an “aspect” does not imply that such aspect is essential to the subject technology or that such aspect applies to all configurations of the subject technology. A disclosure relating to an aspect may apply to all configurations, or one or more configurations. A phrase such as an aspect may refer to one or more aspects and vice versa. A phrase such as a “configuration” does not imply that such configuration is essential to the subject technology or that such configuration applies to all configurations of the subject technology. A disclosure relating to a configuration may apply to all configurations, or one or more configurations. A phrase such as a configuration may refer to one or more configurations and vice versa.

The word “example” is used herein to mean “serving as an example or illustration.” Any aspect or design described herein as “example” is not necessarily to be construed as preferred or advantageous over other aspects or design

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.” Furthermore, to the extent that the term “include,” “have,” or the like is used in the description or the claims, such term is intended to be inclusive in a manner similar to the term “comprise” as “comprise” is interpreted when employed as a transitional word in a claim.

What is claimed is:

1. An electronic device, comprising:
a housing having an opening; and
a pressure sensor disposed within the housing and adjacent to the opening, the pressure sensor comprising:
a sensing membrane configured to obtain pressure data;
a membrane support;
an outer membrane; and
a fluid cavity disposed between the sensing membrane and the outer membrane,
wherein the outer membrane is disposed on the membrane support and encapsulates the fluid cavity and the sensing membrane.

2. The electronic device of claim 1, wherein the outer membrane comprises a semiconductor material.

3. The electronic device of claim 2, wherein the semiconductor material comprises one or more of silicon or nitride.

4. The electronic device of claim 1, wherein the pressure sensor further comprises a reference cavity formed beneath the sensing membrane.

5. The electronic device of claim 1, wherein the outer membrane forms a hermetic seal between the membrane support and the fluid cavity.

6. The electronic device of claim 1, wherein the outer membrane has a spring constant value that is lesser than that of the sensing membrane.

7. The electronic device of claim 1, wherein the outer membrane has a membrane stiffness that is lesser than that of the sensing membrane.

8. The electronic device of claim 1, wherein the outer membrane has a width greater than the sensing membrane.

9. The electronic device of claim 1, wherein the outer membrane has a thickness in a range of 0.2 microns to 25 microns.

10. The electronic device of claim 1, wherein the outer membrane has a width in a range of 200 microns to 2 millimeters.

11. The electronic device of claim 1, wherein the sensing membrane has a thickness in a range of 0.1 microns to 10 microns.

12. The electronic device of claim 1, wherein the fluid cavity has a height in a range of 0.1 micron to 15 microns.

13. The electronic device of claim 1, wherein the membrane support has a temperature coefficient of offset (TCO) value that corresponds to that of a fluid encapsulated within the fluid cavity.

14. The electronic device of claim 1, wherein the pressure sensor is a micro-electromechanical system (MEMS) pressure sensor.

15. An apparatus, comprising:
a substrate;
a sensing membrane disposed on the substrate and configured to obtain pressure data;
a membrane support disposed on the substrate;
an outer membrane disposed on the membrane support;
reference cavity formed between the sensing membrane and the substrate; and
a fluid cavity disposed between the sensing membrane and the outer membrane,
wherein the outer membrane encapsulates the fluid cavity and the sensing membrane.

16. The apparatus of claim 15, wherein the outer membrane has a membrane stiffness that is lesser than that of the sensing membrane.

17. The apparatus of claim 15, wherein the outer membrane has a width greater than the sensing membrane.

18. The apparatus of claim 15, wherein the fluid cavity has a height in a range of 1 micron to 15 microns.

19. The apparatus of claim 15, wherein the membrane support has a temperature coefficient of offset (TCO) value that corresponds to that of a fluid encapsulated within the fluid cavity.

20. A smart watch, comprising:
a housing having an opening; and
a pressure sensor disposed within the housing and adjacent to the opening, the pressure sensor comprising:
a substrate;
a sensing membrane disposed on the substrate and configured to obtain pressure data;
a membrane support disposed on the substrate;
an outer membrane disposed on the membrane support, wherein the outer membrane has a thickness that is smaller than the sensing membrane;
reference cavity formed between the sensing membrane and the substrate; and
a fluid cavity disposed between the sensing membrane and the outer membrane,
wherein the outer membrane forms a hermetic seal between the membrane support and the fluid cavity, and
wherein the outer membrane has a thickness that is smaller than the sensing membrane,
wherein the membrane support has a temperature coefficient of offset value that corresponds to that of a fluid encapsulated within the fluid cavity.
